(19) United States
(12) Patent Application Publication
(10) Pub. No.: US 2024/0249064 A1
(43) Pub. Date: Jul. 25, 2024

(54) ROUTING LAYOUT DESIGN DEVICE AND ROUTING LAYOUT DESIGN METHOD

(71) Applicant: PEGATRON CORPORATION, Taipei City (TW)

(72) Inventor: Yung-Lin Hsieh, Taipei City (TW)

(73) Assignee: PEGATRON CORPORATION, TAIPEI CITY (TW)

(21) Appl. No.: 18/465,451

(22) Filed: Sep. 12, 2023

(30) Foreign Application Priority Data
Jan. 19, 2023 (TW) 112102583

(51) Int. Cl. G06F 30/3953

(52) U.S. Cl. CPC G06F 30/3953

(57) ABSTRACT

A routing layout design device and a routing layout design method are provided. The routing layout design method includes: reading multiple pin information and multiple lead rule information of a circuit board; selecting multiple outer row pins located on an outer edge of the circuit board according to the multiple pin information; generating multiple outer row leads from multiple outer row pins along a direction perpendicular to the outer edge; establishing multiple triangles with the pins as vertices through an algorithm, and selecting a plurality of first pins respectively located in the same triangle as the plurality of outer row pins; coupling the outer row leads to the first pins according to a plurality of lead limiting area, the triangles and the plurality of lead rule information; generating a lead data according to a coupling relationship of the first pins coupled to the outer row leads.

### CROSS-REFERENCE TO RELATED APPLICATION

This application claims the priority benefit of Taiwan application Ser. No. 11/210,2583, filed on Jan. 19, 2023. The entirety of the above-mentioned patent application is hereby incorporated by reference herein and made a part of this specification.

### BACKGROUND

### Technical Field

The present disclosure relates to a routing technology, and in particular to a routing layout design device and a routing layout design method.

### Description of Related Art

In the routing technology of routing a chip packaged in a Ball Grid Array (BGA) to a circuit board, the routing design of the outer row pins of the circuit board is normally performed manually. However, when the routing design is performed manually, the operators generally perform relevant tasks based on their own experiences. During the processing, the operator does not perform the tasks based on the standardized operation process or steps. Moreover, manual routing often requires a lot of try and error and verification to confirm whether the routing is correct, which will increase the overall routing time and affect the accuracy of routing. In view of the foregoing, how to effectively improve the working efficiency of the routing operation will be an important subject for those skilled in the art.

### SUMMARY

The present disclosure provides a routing layout design device and a routing layout design method, which may effectively reduce the overall routing time and improve the routing accuracy.

The routing layout design method of the disclosure is applicable to circuit boards, and the method includes: reading, by a processor, a plurality of pin information and a plurality of lead rule information of a circuit board stored in a memory; selecting, by the processor, a plurality of outer row pins located on an outer edge of the circuit board among a plurality of pins on the circuit board according to a plurality of pin information; generating, by the processor, a plurality of outer row leads from the plurality of outer row pins along a direction perpendicular to the outer edge; establishing, by the processor, a plurality of triangles with the pins as vertices through an algorithm, and selecting a plurality of first pins respectively located in the same triangle as the plurality of outer row pins; coupling, by the processor, the outer row leads to the plurality of first pins according to a plurality of lead limiting areas, the plurality of triangles and the plurality of lead rule information; and generating, by the processor, a lead data according to a coupling relationship between the plurality of first pins coupled to the plurality of outer row leads.

The disclosed routing layout design device is applicable for circuit boards. The routing layout design device includes a memory and a processor. The memory is configured to store circuit board information, where the circuit board information includes a plurality of pin information and a plurality of lead rule information. The processor is coupled to the memory, where the processor is configured to: select a plurality of outer row pins located on an outer edge of the circuit board among a plurality of pins on the circuit board according to a plurality of pin information; generate a plurality of outer row leads from the plurality of outer row pins along a direction perpendicular to the outer edge; establish a plurality of triangles with the pins as vertices through an algorithm, and select a plurality of first pins respectively located in the same triangle as the plurality of outer row pins; couple the outer row leads from the plurality of outer row pins to the plurality of first pins according to a plurality of lead limiting areas, the plurality of triangles and the plurality of lead rule information; and generate a lead data according to a coupling relationship between the plurality of first pins coupled to the plurality of outer row leads.

Based on the above, the routing layout design device and routing layout design method described in the disclosed embodiments may establish multiple triangles among multiple pins on the circuit board information, so that the processor may selectively couple a plurality of first pins among the pins to a plurality of outer row leads according to the triangles and lead rule information. In this way, the processor may obtain the lead data according to the coupling relationship between the first pins and the outer row leads, so as to generate the routing on the circuit board according to the lead data, so as to reduce the overall routing time and achieve the technical effect of improving the accuracy of routing.

### BRIEF DESCRIPTION OF THE DRAWINGS

FIG. 1 is a block diagram illustrating a routing layout design device according to an embodiment of the present disclosure.

FIG. 2 is a schematic diagram of circuit board information according to the embodiment of FIG. 1 of the present disclosure.

FIG. 3A to FIG. 3C are schematic diagrams of partial circuit board information according to the embodiment of FIG. 2 of the present disclosure.

FIG. 4 is a flowchart illustrating a method of calculating a lead turning point on a boundary of a triangle by a processor of the present disclosure.

FIG. 5 is a flowchart illustrating a routing layout design method according to an embodiment of the present disclosure.

### DESCRIPTION OF THE EMBODIMENTS

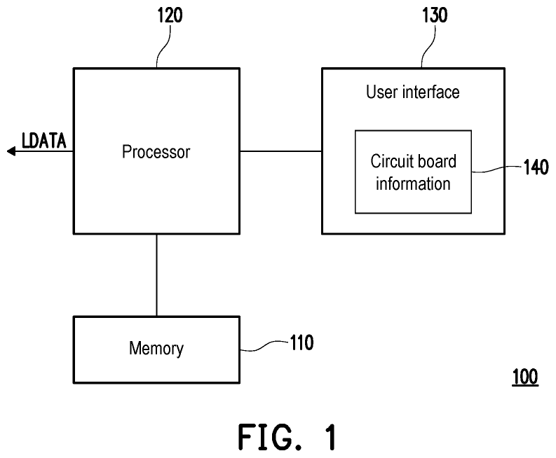

FIG. 1 is a block diagram illustrating a routing layout design device according to an embodiment of the present disclosure. Referring to FIG. 1, the routing layout design device 100 includes a memory 110, a processor 120 and a user interface 130. The processor 120 is coupled between the memory 110 and the user interface 130. The routing layout design device 100 of this embodiment may be, for example, a desktop computer, a notebook computer and/or a tablet computer, but is not limited thereto.

The memory 110 may be, for example, a variable resistive random-access memory (RRAM), a Ferroelectric RAM (FeRAM), a Magnetoresistive RAM (MRAM), a phase change RAM (PRAM), a conductive bridge RAM (CBRAM), but not limited thereto.

In addition, the processor 120 may be, for example, a Central Processing Unit (CPU), or other programmable general-purpose or special-purpose microprocessor, a digital signal processor (DSP), a programmable controller, an application specific integrated circuit (ASIC) or other similar components or a combination of the above components, but not limited thereto.

In this embodiment, in order to allow the operator to use the routing layout design device 100 to plan the layout between the chip and the circuit board packaged in a ball grid array, the memory 110 of the present embodiment may pre-store circuit board information 140 associated with the circuit board. The circuit board information 140 may include a plurality of pin information and a plurality of lead rule information about the circuit board.

For example, the pin information may include distribution states of a plurality of components and a plurality of pins on the circuit board. Moreover, the pin information may also include a plurality of pin type information. The pin type information may be respectively used to denote the functions and/or types of the multiple pins of the circuit board. A first pin type of these pin type information may be denoted as a power pin for receiving power signal, and a second pin type of these pin type information may be denoted as ground pin for receiving ground signal. In addition, a third pin type of the pin type information may be denoted as a signal pin for receiving general signals, and a fourth pin type of the pin type information may be denoted as a dummy pin not receiving any signal.

On the other hand, the lead rule information in the circuit board information 140 may be used to indicate the required line width and line distance of routing for each pin.

In this embodiment, the processor 120 may read the circuit board information 140 pre-stored in the memory 110 from the memory 110, and may provide the circuit board information 140 to the user interface 130, to be integrated and displayed through the user interface 130. In this way, the operator may complete the routing layout planning between the chip and the circuit board by operating the user interface 130 of the routing layout design device 100 and using the circuit board information 140 in the user interface 130.

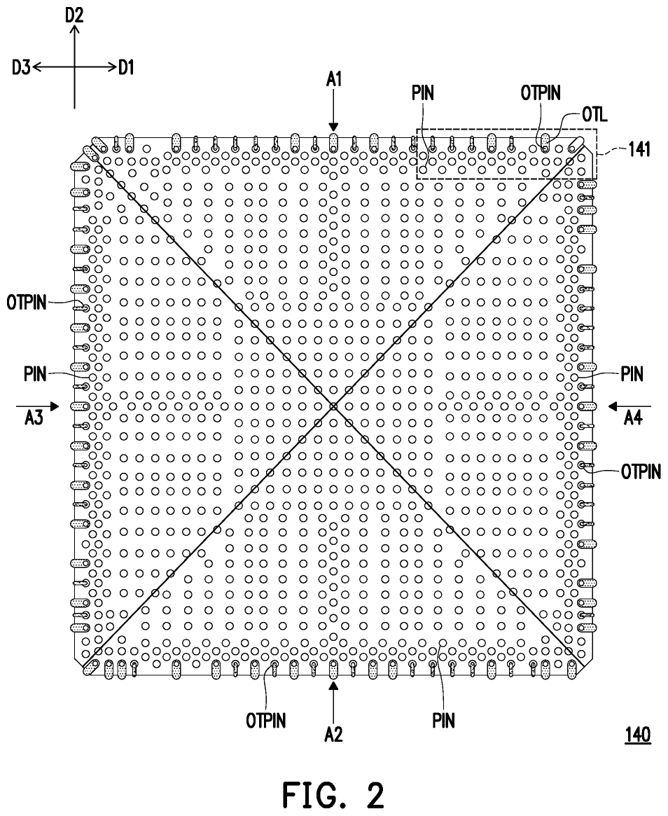

FIG. 2 is a schematic diagram of circuit board information according to the embodiment of FIG. 1 of the present disclosure. Referring to FIG. 2, the circuit board information 140 in this embodiment may include the distribution status of a plurality of components and a plurality of pins in the circuit board.

It should be noted that, for the clarity of drawings, in the content shown in FIG. 2, a plurality of pins surrounding the outermost row of the circuit board may be represented by a symbol OTPIN as a plurality of outer row pins of the circuit board, and the pins arranged within these outer row pins OTPIN may be represented by the symbol PIN as the rest of the multiple pins on the circuit board. In addition, FIG. 2 may use the symbol OTL to represent a plurality of outer row leads generated from the outer row pins OTPIN of the circuit board.

Please refer to FIG. 1 and FIG. 2 for the operation details and flow of the routing layout design device 100. In this embodiment, the processor 120 may first distinguish all the pins in the circuit board (that is, a plurality of outer row pins OTPIN and a plurality of pins PIN) into multiple areas according to the circuit board information 140. For example, the processor 120 may divide all the pin areas in the circuit board into an upper half area A1, a lower half area A2, a left half area A3 and a right half area A4 according to the number of outer edges (for example, 4) of the circuit board.

It should be noted that the following description will take the upper half area A1 of the circuit board information 140 as an example for illustration, while the lower half area A2, the left half area A3, and the right half area A4 of the remaining circuit board information 140 may be deduced by analogy.

After the processor 120 divides these pins PIN and OTPIN into a plurality of areas A1 to A4, the processor 120 may select a plurality of outer row pins OTPINs located on the outer edge of the circuit board and arranged in the first direction D1 (that is, to the right direction) from each of the areas A1 to A4 (taking the upper half area A1 as an example) according to the pin information, and make these outer row pins OTPIN to generate multiple outer row leads OTL to the component boundary of the circuit board along the second direction D2 (that is, to the upward direction), where the first direction D1 and the second direction D2 are perpendicular to each other.

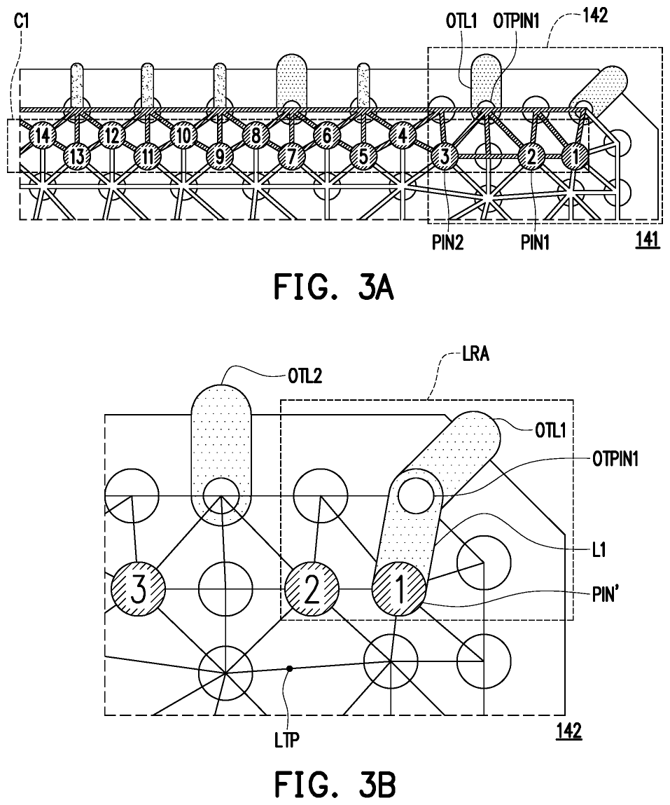

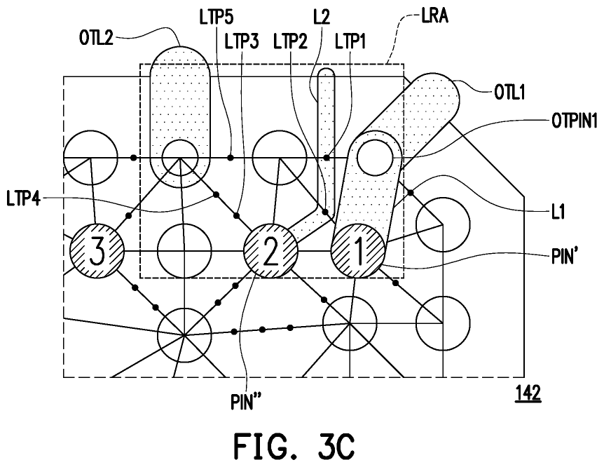

It should be mentioned that for the convenience of description, the relevant content of the following FIG. 3A will be described as an example in continuation of the partial circuit board information 141 shown in FIG. 2, while the remaining parts or areas of the circuit board information 140 may be deduced by referring to the relevant description of the partial circuit board information 141 shown in FIG. 3A, and thus the details will not be repeated here.

FIG. 3A to FIG. 3C are schematic diagrams of partial circuit board information according to the embodiment of FIG. 2 of the present disclosure. Please refer to FIG. 1 to FIG. 3A at the same time. In this embodiment, the processor 120 may establish a plurality of triangles with these pins as vertices on the local circuit board information 141 (or circuit board information 140) through an algorithm. In addition, multiple pins PINs located in the same triangle as the outer row pins OTPIN may be selected, where the algorithm in this embodiment may be, for example, a Delaunay Triangulation algorithm, but this disclosure is not limited thereto.

For example, as shown in FIG. 3A, the processor 120 may form a triangle with the two pins PIN1 and PIN2 and the outer pin OTPIN1 as three vertices through the algorithm, and the remaining pins (or outer row pins) may also form a corresponding triangle with adjacent pins.

After establishing a plurality of triangles on the local circuit board information 141, the processor 120 may obtain multiple pins which form the triangles with these outer row pins (for example, the outer row pin OTPIN1) from the first inner row information C1 according to an algorithm (for example, pins PIN1 and PIN2).

Next, the processor 120 may sequentially select a pin from the multiple pins arranged along the third direction D3 according to the preset lead sequence in the first inner row information C1 as the selected pin. The numbers 1 to 14 shown in FIG. 3A may represent the priority order of the selected pins.

That is to say, the processor 120 may perform routing actions on multiple pins in the first inner row information C1 according to a preset priority order. The first direction D1 and the third direction D3 are opposite to each other, and the second direction D2 and the third direction D3 are perpendicular to each other.

In this regard, for the convenience of description, the relevant content of the following FIG. 3B and FIG. 3C will be described with the partial circuit board information 142 shown in

FIG. 3A as an example, and the remaining parts or areas of the circuit board information 140 or the partial circuit board information 141 may be deduced by referring to the relevant descriptions of the partial circuit board information 142 shown in FIG. 3B and FIG. 3C, so details are not repeated.

Please refer to FIG. 1 to FIG. 3B at the same time. In this embodiment, the processor 120 may then calculate an average distance between adjacent pins according to the positions of all pins in the circuit board information 140. Moreover, after the processor 120 selects the selected pin and calculates the relevant information of the average distance between all pins, the processor 120 may obtain the lead limiting area LRA according to the position of the selected pin and the average distance between the pins.

For example, as shown in FIG. 3B, when the processor 120 selects the pin PIN′ from the first inner row information C1 according to the order of the leads as the first selected pin (that is, the pin denoted by numeral 1), the processor 120 may use the pin PIN′ as the center and form a rectangular lead limiting area LRA according to the average distance of the pins along the first direction D1, the second direction D2, and the third direction D3 of the pin PIN′.

In this regard, assuming that the average distance between the pins in this embodiment is 32.39 mils, the processor 120 will set the distance between the pin PIN′ and the boundary of the lead limiting area LRA in the first direction D1 to be 32.39 mil, set the distance between the pin PIN′ and the boundary of the lead limiting area LRA in the second direction D2 to be 32.39 mil, and set the distance between the pin PIN′ and the boundary of the lead limiting area LRA in the third direction D3 to be 32.39 mil.

Next, after the processor 120 establishes the lead limiting area LRA of the local circuit board information 142, the processor 120 will find out a plurality of triangles overlapping with the lead limiting area LRA, and obtain the required line width and line distance for the lead of the pin PIN′ (that is, the selected pin) according to the lead rule information. Next, the processor 120 calculates one or more lead turning points (for example, lead turning points LTP shown in FIG. 3B) on multiple boundaries of the triangles overlapping with the lead limiting area LRA according to the obtained line width and line distance.

At this step, the processor 120 may determine whether the pin PIN′ maybe coupled to the outer edge of the circuit board via these lead turning points. When the processor 120 determines that the pin PIN′ is not able to be coupled to the outer edge of the circuit board via these lead turning points, the processor 120 will further determine the pin types of the pin PIN′ and the multiple outer row pins of the local circuit board information 142 according to the pin information.

For example, in the embodiment shown in FIG. 3B, when the processor 120 determines that the pin PIN′ will pass through or touch the boundary of other triangles that are not available when being coupled to the outer edge of the circuit board via the lead turning point LTP, the processor 120 will determine that the pin PIN′ is not able to be coupled to the outer edge of the circuit board via these lead turning points.

In this case, the processor 120 will further determine the pin types of the pin PIN′ and the plurality of outer row pins of the local circuit board information 142 according to the pin information. In one case, if the processor 120 determines the outer row pin OTPIN1 of the local circuit board information 142 belongs to the first pin type or the second pin type according to the pin information, the processor 120 may make the pin PIN′ generate a lead L1, and couple to the outer row lead OTL1 on the outer row pin OTPIN1 of the same pin type.

In another case, when the processor 120 determines that the pin PIN′ belongs to the third pin type or the fourth pin type, it means that the pin type of the pin PIN′ is different from that of the outer row pin OTPIN1 of the local circuit board information 142. In this case, the processor 120 may correspondingly generate a failure prompt message on the user interface 130. In this way, the operator may manually route the pin PIN′ through the user interface 130 and according to the failure prompt message.

After the processor 120 completes the routing action of the first selected pin (that is, the pin PIN′), as shown in FIG. 3C, the processor 120 will continue to plan the layout of the pin PIN″ numbered 2. Specifically, the processor 120 may re-center on the pin PIN″ (that is, the selected pin), and form a rectangular lead limiting area LRA along the first direction D1, the second direction D2 and the third direction D3 of the pin PIN″ according to the average distance of the pins.

Then, the processor 120 may obtain the required line width and line distance of the leads of the pin PIN″ according to the lead rule information, and calculate one or more lead turn points (e.g., lead turn points LTP1 to LTP5 shown in FIG. 3C) on multiple boundaries of each triangle according to the line width and line distance required for the leads of the pin PIN″.

On the other hand, the processor 120 will calculate or find out the lead turning points

LTP1 and LTP2 closest to the previously selected pin PIN′ as the selected lead turning points from the plurality of lead turning points LTP1 to LTP5 in overlapping portions with the lead limiting area LRA and the boundary of the triangle according to the lead rule information.

Then, the processor 120 determines that the lead L2 will not pass through or touch the boundary of other triangles if the pin PIN″ is coupled along the calculated and selected lead turning points LTP1 and LTP2, it means that the processor 120 determines that the pin PIN″ maybe coupled to the outer edge of the circuit board through the selected lead turning points LTP1 and LTP2. Therefore, the processor 120 may make the pin PIN″ generate the lead L2 along the second direction D2 according to the selected lead turning points LTP1 and LTP2, and couple the lead L2 to the corresponding outer row leads.

It is worth mentioning that the routing planning of the rest of the pins in the first inner row information C1 may be analogized with reference to the relevant descriptions of the pins PIN′ and PIN″ in FIG. 3B and FIG. 3C, so the details are not repeated.

In this way, after completing the routing planning of all the pins in each area A1 to A4, the processor 120 may generate the lead data LDATA according to the coupling relationship between all the pins, and generate leads on the circuit board through the lead data LDATA. In this way, the routing layout design device 100 of this embodiment may effectively reduce the overall routing time of the circuit board and improve the routing accuracy.

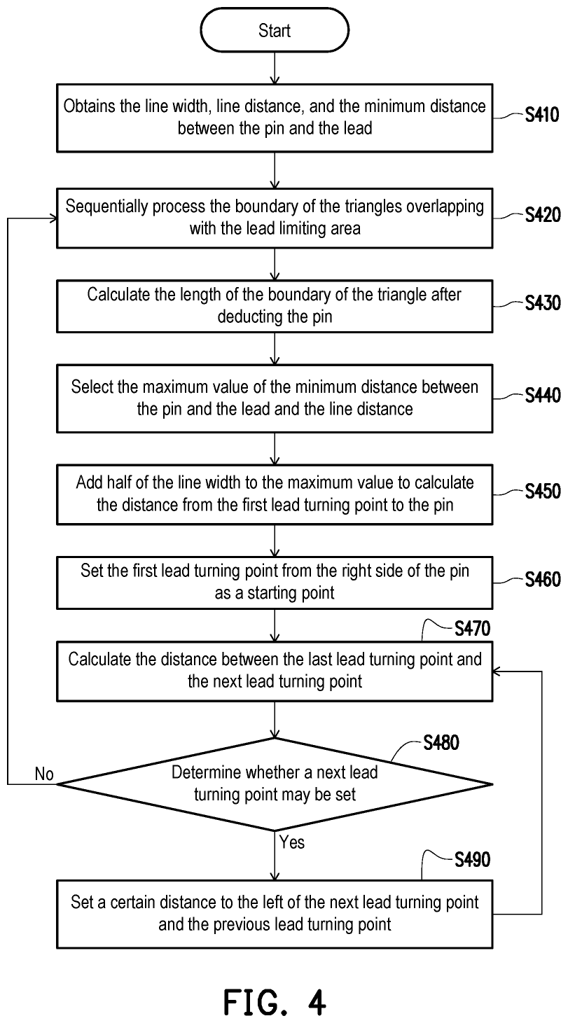

On the other hand, please refer to FIG. 1 to FIG. 4 at the same time for the implementation details of the processor 120 calculating the corresponding lead turning point according to the lead rule information. FIG. 4 is a flowchart illustrating a method of calculating a lead turning point on a boundary of a triangle by a processor of the present disclosure.

After the processor 120 starts to calculate these lead turning points, in step S410, the processor 120 firstly obtains the line width and line distance of the lead generated by the selected pin and the minimum distance between the selected pin and the lead according to the lead rule information.

For example, taking the embodiment of FIG. 3C as an example, the processor 120 may obtain that, according to the lead rule information, the line width of the lead L2 generated by the selected pin PIN″ is 3.5 mil, the line distance is 3.5 mil, and the minimum distance between the selected pin PIN″ and the lead L2 is 4 mil.

Next, in step S420, the processor 120 may sequentially process the boundary of the triangles overlapping the LRA with the lead limiting area. In step S430, the processor 120 may calculate the length of the boundary of the triangle formed between adjacent pins after deducting the selected pin PIN″.

Next, in step S440, the processor 120 may select the maximum value of the minimum distance between the selected pin and the lead and the line distance. For example, assuming that the processor 120 may choose the maximum value of 4 mil when obtaining that, according to the lead rule information, the line distance of the selected pin is 3.5 mil, and the minimum distance between the selected pin and the lead is 4 mil.

Next, in step S450, the processor 120 may add half of the line width (that is, 1.75 mil) to the maximum value (that is, 4 mil) to calculate the distance from the first lead turning point to the selected pin. Moreover, in step S460, the processor 120 may set the first lead turning point from the right side of the pin as a starting point.

Next, in step S470, the processor 120 may calculate the distance between the last lead turning point and the next lead turning point (i.e., line width 3.5 mil+line distance 3.5 mil=7 mil). Moreover, in step S480, the processor 120 may determine whether a next lead turning point may be set. When the determining result of the processor 120 in step S480 is yes, the operation of step S490 is continued. On the contrary, when the determining result of the processor 120 in the step S480 is negative, the operation of the step S420 is continued. In step S490, the processor 120 may set a certain distance to the left of the next lead turning point and the previous lead turning point.

The operation actions of the above-mentioned steps S410 to S490 may be analogized with reference to the relevant descriptions of the embodiment in FIG. 3B and FIG. 3C, so no more details are repeated.

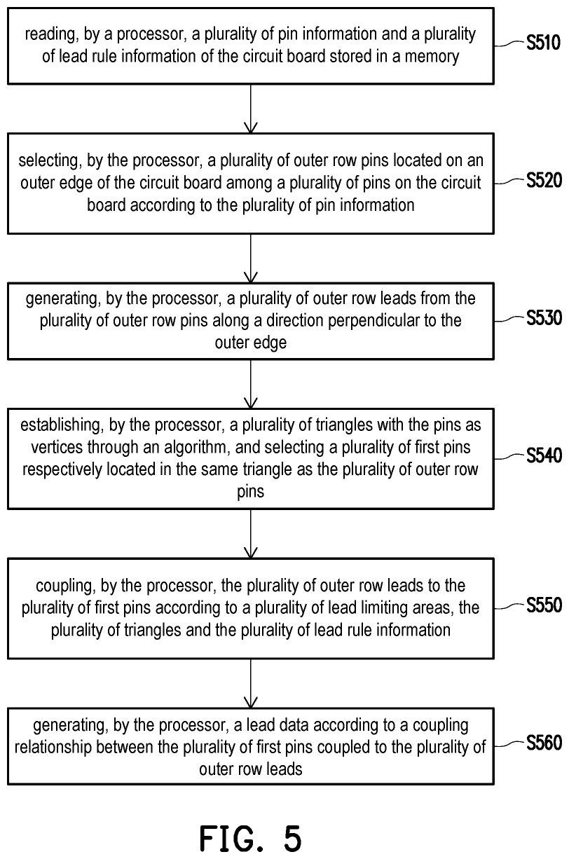

FIG. 5 is a flowchart illustrating a routing layout design method according to an embodiment of the present disclosure. Please refer to FIG. 1 and FIG. 5 at the same time. In step S510, the lead processing device 100 may read a plurality of pin information and a plurality of lead rule information of the circuit board stored in the memory 110 through the processor 120.

In step S520, the lead processing device 100 may use the processor 120 to select a plurality of outer row pins located on an outer edge of the circuit board among the plurality of pins on the circuit board according to the plurality of pin information.

In step S530, the lead processing device 100 may use the processor 120 to generate a plurality of outer row leads from the plurality of outer row pins along a direction perpendicular to the outer edge. In step S540, the routing layout design device 100 may use the processor 120 to establish a plurality of triangles with a plurality of pins as vertices through an algorithm, and select a plurality of first pines that are respectively located in the same triangle as the plurality of outer row pins.

In step S550, the routing layout design device 100 may use the processor 120 to couple the plurality of outer row pines to the plurality of first pins according to the lead limiting area, the plurality of triangles and the plurality of lead rule information. In step S560, the routing layout design device 100 may use the processor 120 to generate lead data according to the coupling relationship between the plurality of first pins coupled to the plurality of outer row leads.

The implementation details of each step have been described in detail in the foregoing embodiments and implementation modes, and will not be repeated here.

To sum up, the routing layout design device and the routing layout design method described in the disclosed embodiments may establish multiple triangles among multiple pins on the circuit board information through the Delaunay triangulation algorithm, so that the processor may selectively couple a plurality of first pins among the pins to a plurality of outer row leads according to the triangles and the lead rule information. In this way, the processor may obtain the lead data according to the coupling relationship between the first pins and the outer row leads, so as to generate the leads on the circuit board according to the lead data, so as to reduce the overall routing time and the technical effect of improving the accuracy of routing.

What is claimed is:

1. A routing layout design method, adaptable for a circuit board, comprising:
reading, by a processor, a plurality of pin information and a plurality of lead rule information of the circuit board stored in a memory;
selecting, by the processor, a plurality of outer row pins located on an outer edge of the circuit board among a plurality of pins on the circuit board according to the plurality of pin information;
generating, by the processor, a plurality of outer row leads from the plurality of outer row pins along a direction perpendicular to the outer edge;
establishing, by the processor, a plurality of triangles with the pins as vertices through an algorithm, and selecting a plurality of first pins respectively located in the same triangle as the plurality of outer row pins;
coupling, by the processor, the plurality of outer row leads from the plurality of outer row pins to the plurality of first pins according to a plurality of lead limiting areas, the plurality of triangles and the plurality of lead rule information; and
generating, by the processor, a lead data according to a coupling relationship between the plurality of first pins coupled to the plurality of outer row leads.

2. The routing layout design method according to claim 1, further comprising:
calculating, by the processor, a pin average distance between the plurality of adjacent pins according to the pin information; and
obtaining, by the processor, the plurality of lead limiting areas respectively corresponding to the plurality of pins are according to the pin average distance.

3. The routing layout design method according to claim 2, further comprising:
taking, by the processor, each of the plurality of pins as a center and extending the pin average distance of the plurality of pins toward the direction and two opposite directions perpendicular to the direction to form the rectangular lead limiting area.

4. The routing layout design method according to claim 1, further comprising:
calculating, by the processor, a plurality of lead turning points on boundaries of the triangles within the lead limiting area according to the lead rule information; and
coupling, by the processor, the plurality of outer row leads to the plurality of first pins via the plurality of lead turning points.

5. The routing layout design method according to claim 4, further comprising:
determining, by the processor, whether one of the plurality of first pins is able to be coupled to the outer edge through the plurality of lead turning points;
when the processor determines that one of the plurality of first pins is not able to be coupled to the outer edge through the plurality of lead turning points, the one of the first pins is coupled to one of the plurality of outer rows of pins with the same pin type.

6. The routing layout design method according to claim 1, further comprising:
dividing, by the processor, the plurality of pin areas into a plurality of areas according to the number of outer edges of the circuit board.

7. The routing layout design method according to claim 1, wherein the algorithm is a Delaunay Triangulation algorithm.

8. A routing layout design device, adaptable for a circuit board, comprising:
a memory, configured to store a plurality of pin information and a plurality of lead rule information of the circuit board; and
a processor, coupled to the memory, and configured to:
read the plurality of pin information and the plurality of lead rule information;
select a plurality of outer row pins located on an outer edge of the circuit board among a plurality of pins on the circuit board according to the plurality of pin information;
generate a plurality of outer row leads from the plurality of outer row pins along a direction perpendicular to the outer edge;
establish a plurality of triangles with the plurality of pins as vertices through an algorithm, and select a plurality of first pins respectively located in the same triangle as the plurality of outer row pins;
couple the plurality of outer row leads from the plurality of outer row pins to the plurality of first pins according to a plurality of lead limiting areas, the plurality of triangles and the plurality of lead rule information; and
generate a lead data according to a coupling relationship between the plurality of first pins coupled to the plurality of outer row leads.

9. The routing layout design device according to claim 8, wherein the processor is further configured to:
calculate a pin average distance between the plurality of adjacent pins according to the pin information; and
obtain the plurality of lead limiting areas respectively corresponding to the plurality of pins are according to the pin average distance.

10. The routing layout design device according to claim 9, wherein the processor is further configured to:
take each of the plurality of pins as a center and extend the pin average distance of the pins toward the direction and two opposite directions perpendicular to the direction to form the rectangular lead limiting area.

11. The routing layout design device according to claim 8, wherein the processor is further configured to:
calculate a plurality of lead turning points on boundaries of the triangles within the lead limiting area according to the lead rule information; and
couple the plurality of outer row leads to the plurality of first pins via the plurality of lead turning points.

12. The routing layout design device according to claim 11, wherein the processor is further configured to:
determine whether one of the plurality of first pins is able to be coupled to the outer edge through the plurality of lead turning points; and
when it is determined that one of the plurality of first pins is not able to be coupled to the outer edge through the plurality of lead turning points, the one of the plurality of first pins is coupled to one of the plurality of outer rows of pins with the same pin type, and generates the plurality of outer row leads from the plurality of outer row pins along the direction perpendicular to the outer edge.

13. The routing layout design device according to claim 11, wherein the processor is further configured to:
divide the plurality of pin areas into a plurality of areas according to the number of outer edges of the circuit board.

14. The routing layout design device according to claim 8, wherein the algorithm is a Delaunay Triangulation algorithm.
